(19) United States
(12) Patent Application Publication
(10) Pub. No.: US 2026/0353875 A1
(43) Pub. Date: Nov. 5, 2026

(54) Display Device and Method for Producing Same

(71) Applicant: LG Display Co., Ltd., Seoul (KR)

(72) Inventors: Yong Seok Kwak, Paju-si (KR); Min Jae Kang, Seoul (KR)

(21) Appl. No.: 19/734,656

(22) Filed: Jul. 8, 2026

Related U.S. Application Data
(63) Continuation of application No. 17/919,727, filed on Apr. 30, 2021, now Pat. No. 12,707,772.

(30) Foreign Application Priority Data
Jun. 30, 2020 (KR) 10-2020-0080152

(51) Int. Cl. H10H 20/851; H10D 86/40; H10D 86/60; H10H 20/857; H10W 90/00; H10H 20/01

(52) U.S. Cl. CPC H10H 20/8512; H10D 86/441; H10D 86/60; H10H 20/8514; H10H 20/857; H10W 90/00; H10H 20/0361; H10H 20/0364

(57) ABSTRACT

A display device according to an embodiment of the present invention comprises a color conversion substrate and a color conversion layer which convert light of a first color emitted by an LED to a second color and emit the light in all directions. The present invention can reduce LED transfer processes as the color conversion layer is included, and light-emitting efficiency can be increased by using the side-surface light emitted from the LEDs.

### CROSS-REFERENCE TO RELATED APPLICATION

This application is a continuation application of U.S. Patent Application No. 17/919,727 filed on October 18, 2022, which is a U.S. National Phase Application corresponding to International Application No. PCT/KR2021/005499 filed on April 30, 2021, which claims priority to Republic of Korea Patent Application No. 10-2020-0080152 filed on June 30, 2020, all of which are incorporated by reference herein.

### TECHNICAL FIELD

The present disclosure relates to a display device, and more particularly, to a display device which converts a color of light emitted from an LED into a specific color and emits the light.

### BACKGROUND ART

Following a Liquid Crystal Display Device (LCD), which is used so far, use and application ranges of an Organic Light Emitting Display Device (OLED) are gradually expanding.

In order to implement an image, a plurality of light emitting elements and liquid crystals are disposed on a substrate on a display device, and a driving element supplying a driving signal to individually control operations of respective light emitting elements and liquid crystals is disposed jointly with the light emitting element to display the plurality of light emitting elements and the liquid crystals disposed on the substrate according to information to be displayed.

Since the liquid crystal display device is not a self-luminous scheme, a backlight unit disposed on a rear surface of the liquid crystal display device for emitting light is required. The backlight unit has a restriction in increasing a thickness of the liquid crystal display device, and implementing the display device with various types of designs such as flexible or circular, and luminance and a response speed of the backlight unit may be reduced.

Meanwhile, since the display device with the self-luminous element may be implemented thinner than a display device a light source embedded therein, a display device which is flexible and foldable can be implemented. The display device with the self-luminous element may be an organic light emitting display device containing an organic matter as an active layer, and since the organic light emitting display device does not require a separate light source by self-light emitting, the organic light emitting display device can be used as thinner and various types of display devices.

However, in the organic light emitting display device using the organic matter, since bad pixels are easily generated due to an oxidation phenomenon between an organic active layer and an electrode by penetration of moisture and oxygen, various technical configurations for minimizing the penetration of the oxygen and the moisture are additionally required.

Therefore, in recent years, in order to overcome the problems of the liquid crystal display device and/or the organic light emitting display device, an LED display device using a light emitting diode (LED) as the light emitting element has been proposed.

The display device as a display device in which a mini or micro sized subminiature LED using an inorganic matter as the light emitting element in a subpixel may implement a high-definition image by using the inorganic matter as the light emitting element, and implement a high-reliability and long-lifespan display device resistant to a defect such as moisture penetration.

In general, the LED display device is implemented by growing the LED on a sapphire substrate, separating the LED from the sapphire substrate, and transferring the LED to a transistor substrate.

In this case, a size of the LED is very small and difficulties of separation and transfer processes of the LED are high, so there is a problem in that it is difficult to enhance accuracy and yield of the process.

Further, light generated from the LED proceeds in omni directions including an upper portion, a lateral portion, and a lower portion, but only light radiated to the upper portion is expressed to the outside to display the image, and light in remaining directions is destroyed in the display device, so light emitting efficiency decreases.

### DISCLOSURE

### TECHNICAL PROBLEM

The present disclosure is directed to providing a structure which is capable of enhancing luminous efficiency of a display device using an LED, and simplifying a transfer process.

Objects of the present disclosure are not limited to the above-mentioned objects, and other objects, which are not mentioned above, can be clearly understood by those skilled in the art from the following descriptions.

### TECHNICAL SOLUTION

One aspect of the present disclosure provides a display device which may be configured to include: a first color conversion layer having a thin-film transistor and an LED disposed on a substrate, and converting light of a first color emitted from the LED into a second color. In addition, the first color conversion layer includes a nano fluorescent body made of an inorganic material to absorb light of a specific wavelength emitted from the LED and emit light of another wavelength omnidirectionally. Therefore, light emitted from a blue LED and radiated toward a lateral surface may be absorbed by the first color conversion layer and converted into red light, and emitted upward to increase luminous efficiency.

In addition, when the first color conversion layer converting blue light into the red light is applied, the blue LED may be transferred to a blue subpixel area and a red subpixel area at once. A process of transferring an existing red LED to a red subpixel may be omitted, so there is an advantage in terms of manufacturing cost reduction and yield. Further, a first red color conversion layer transferring the blue LED to the red subpixel area, the blue subpixel area, and a green subpixel area, and converting the blue light into the red light, and a first green color conversion layer converting the blue light into green light may also be applied.

In addition, a color conversion substrate may be disposed on a display substrate. The color conversion substrate which absorbs light which is not absorbed by the first color conversion layer but passes through the first color conversion layer and emits the absorbed light, may perform the same function as the first color conversion layer.

The color conversion substrate may be configured by configuring a second color conversion layer at a position corresponding to the first color conversion layer, and arranging a transparent film at an upper portion of the second color conversion layer, and arranging an adhesive layer at a lower portion. The color conversion substrate may be attached onto the first color conversion layer by the adhesive layer at the lower portion.

Other detailed matters of the exemplary embodiments are included in the detailed description and the drawings.

### ADVANTAGEOUS EFFECTS

According to an example embodiment of the present disclosure, a first color conversion layer surrounding an LED and a second color conversion layer at a position corresponding to the first conversion layer are disposed to reuse LED light radiated toward both sides, thereby enhancing luminous efficiency.

Further, according to an example embodiment of the present disclosure, an LED transfer process is reduced to decrease manufacturing cost and enhance yield.

### DESCRIPTION OF DRAWINGS

FIG. 1A is a diagram illustrating primary transfer for implementing a display device according to an example embodiment of the present disclosure.

FIG. 1B is a diagram illustrating secondary transfer for implementing a display device according to an example embodiment of the present disclosure.

FIG. 2 is a cross-sectional view specifically illustrating a structure of a display device according to an example embodiment of the present disclosure.

FIG. 3 is a diagram illustrating a light emitting ratio depending on a direction of an LED according to the present disclosure.

FIG. 4 is a cross-sectional view illustrating one pixel configuration according to an example embodiment of the present disclosure.

FIG. 5 is a cross-sectional view illustrating one pixel configuration according to another example embodiment of the present disclosure.

FIG. 6A is a diagram illustrating a conversion rate of converting blue light to red light according to a color conversion layer thickness and a nano fluorescent body concentration in a color conversion layer according to the present disclosure.

FIG. 6B is a diagram illustrating a blue light absorption rate changed according to the color conversion layer thickness and the nano fluorescent body concentration in the color conversion layer according to the present disclosure.

FIG. 6C is a diagram illustrating a viscosity of a color conversion material depending on the nano fluorescent body concentration according to the present disclosure.

FIG. 7A is a cross-sectional view illustrating a color conversion substrate of a display device according to another example embodiment of the present disclosure.

FIG. 7B is a cross-sectional view illustrating a color conversion substrate of a display device according to another example embodiment of the present disclosure.

FIGS. 8A-8H are diagrams illustrating a process of manufacturing a display device according to an example embodiment of the present disclosure.

FIGS. 9A-9E are diagrams illustrating a process of manufacturing a color conversion substrate of a display device according to an example embodiment of the present disclosure.

### MODES OF THE INVENTION

Detailed contents for achieving the present disclosure will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

A display device in the present disclosure may be applied to an LED display device, but is not limited thereto and may be applied to various display devices.

Hereinafter, a light emitting display device according to exemplary embodiments of the present disclosure will be described in detail with reference to accompanying drawings.

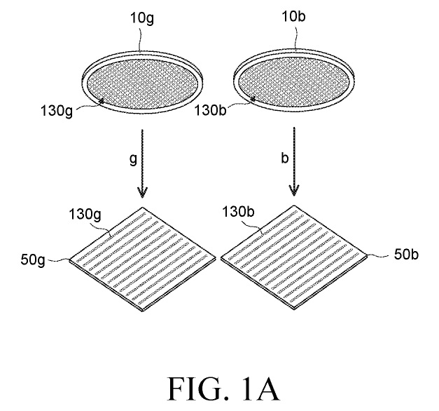

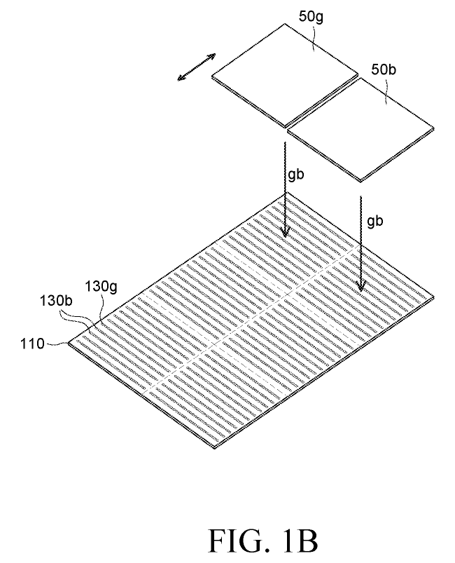

FIGS. 1A and 1B illustrate a transfer method of an LED 130 disposed on a display substrate 110 and used as a subpixel according to an example embodiment of the present disclosure. Here, the LED 130 means all LEDs 130 used in the display device according to the example embodiment of the present disclosure. That is, the LED 130 includes both a blue LED 130b and a green LED 130g.

In order to transfer the LED 130 onto the display device 110, wafers 10g and 10b such as sapphire or silicon are prepared, and then an n-type electrode, an n-type layer, an active layer of a multi-quantum well structure, a p-type layer, and a p-type electrode are sequentially grown on the wafers 10g and 10b by an epitaxial growth method by metal organic chemical vapor deposition (MOCVD) to form a green LED 130g and the blue LED 130b. That is, the green LED 130g is formed in a green wafer 10g and the blue LED 130b is formed in the blue wafer 10b. The green LED 130g and the blue LED 130b formed in the wafers 10g and 10b, respectively are primarily transferred to donor substrates 50g and 50b, respectively.

Next, referring to FIG. 1B, each of the green LED 130g and the blue LED 130b transferred to the donor substrates 50g and 50b, respectively is secondarily transferred to one display substrate110 in which a thin film transistor and various wires are formed, and the LED is connected the thin film transistor and a common wire by a connection wire to manufacture the display device.

As described above, the display device of the present disclosure may be formed by separately manufacturing the display substrate 110 in which the thin film transistor and various wires are formed, and the LED 130, and then transferring the manufactured LED 130 to the display substrate 110. That is, a plurality of LEDs 130 is manufactured on the wafer 10 made of sapphire or silicon and primarily transferred to the donor substrate 50, and secondary transferred to the display substrate 110 from the donor substrate 50 to complete the display device.

Each LED 130 transferred onto the display substrate 110 is transferred to a subpixel area constituting one pixel to become the subpixel. The subpixel area is an area in which the LED used as the subpixel, and a driving circuit are disposed, and the example embodiment of the present disclosure includes a red subpixel area, a green subpixel area, and a blue subpixel area. Various colors of light may be emitted from one pixel by a combination of the plurality of subpixels, and the plurality of pixels is combined to display various images.

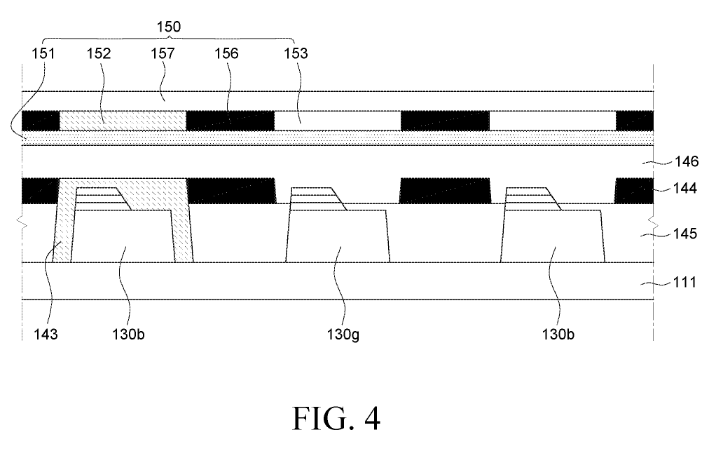

Referring to FIGS. 1B and 4, a plurality of green LEDs 130g and blue LEDs 130b are transferred onto the display substrate 110. Specifically, the plurality of green LEDs 130g is transferred to a green subpixel area and the plurality of blue LEDs 130b is transferred to a blue subpixel area and a red subpixel area. In the case of a transfer order, the green LED may be first transferred to the green subpixel area, and then the blue LED may be simultaneously transferred to the blue subpixel area and the red subpixel area, and it is also possible that the LEDs are transferred in a reverse order.

When the plurality of blue LEDs is transferred to the blue subpixel area and the red subpixel area at once, an existing process of transferring the red LED to the red subpixel area may be omitted, so there is an advantage in terms of manufacturing cost reduction and yield.

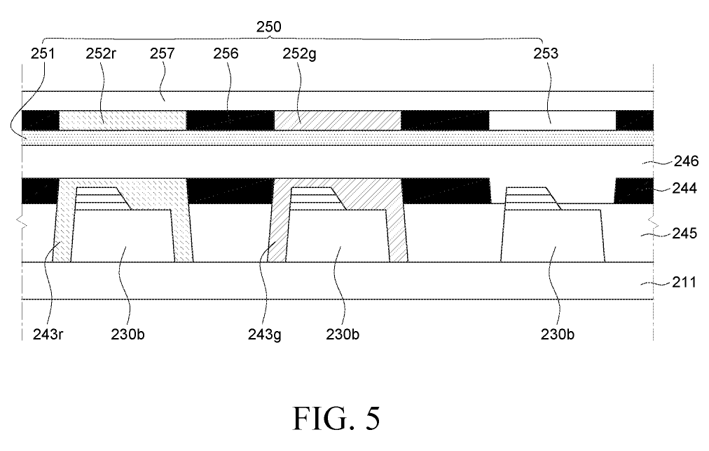

Further, as illustrated in FIG. 5, when the plurality of blue LEDs 230b is transferred to the red subpixel area, the blue subpixel area, and the green subpixel area, the existing processes of transferring the green LED and the red LED may be all omitted, so there are more advantages.

As such, in order to reduce the transfer process, a color conversion layer for converting blue light emitted from the plurality of blue LEDs 130b into red light or green light should be additionally configured.

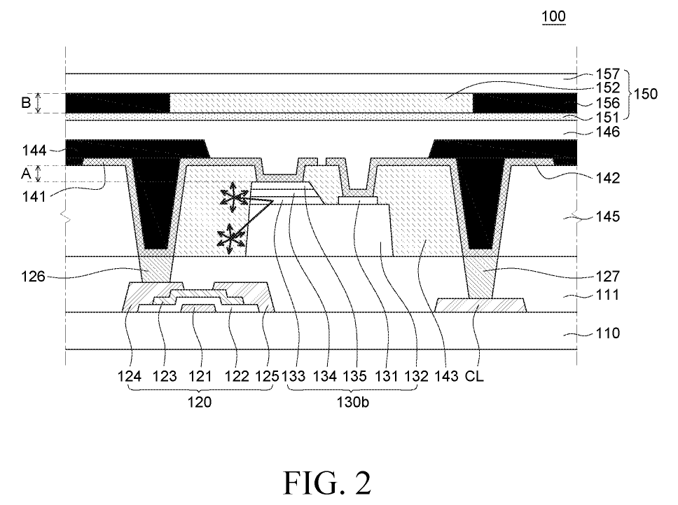

FIG. 2 is a cross-sectional view illustrating a structure of a display device including a color conversion layer according to an example embodiment of the present disclosure.

Referring to FIG. 2, a blue LED 130b, a first color conversion layer 143, and a second color conversion 152 are disposed in a red emitting area of the display device 100. Specific contents of the color conversion layer will be described below, and first, a driving circuit and the LED 130b disposed at a lower portion and a lateral portion of the blue LED 130b will be described in detail.

The driving circuit may be disposed at the upper portion or the lower portion of the display substrate 110, and the driving circuit may be constituted by a plurality of thin-film transistors 120 and a capacitor (not illustrated). The plurality of thin-film transistors 120 may be constituted by a switching thin-film transistor and a driving thin-film transistor.

The thin-film transistor 120 is constituted by a gate electrode 121, an active layer 123, a source electrode 124, and a drain electrode 125. Specifically, the gate electrode 121 is disposed on the substrate 110, and the active layer 123 is disposed on the gate electrode 121. A gate insulating layer 122 for insulating the gate electrode 121 and the active layer 123 is disposed between the gate electrode 121 and the active layer 123. The source electrode 124 and the drain electrode 125 are disposed on the active layer 123.

In FIG. 2, a bottom gate type thin-film transistor is illustrated as described above, but the example embodiment of the present disclosure is not limited thereto. For example, thin-film transistors having various structures such as a top gate type thin-film transistor may be adopted in addition to the bottom gate type.

A common wire CL is disposed on a lateral surface of the thin-film transistor 120 with a material which is the same as a gate electrode material or a source electrode/drain electrode material.

The common wire CL transfers commonly used first power voltage Vss to the LED 130. Specifically, the common wire CL transfers the first power voltage Vss to an n-type electrode of the LED 130 to be described below.

In addition, a first planarization layer 111 for protecting and planarizing the thin-film transistor 120 is disposed on the source electrode 124, the drain electrode 125, and the common wire CL.

In addition, the LED 130 is disposed on the first planarization layer 111 through the transfer process described in FIGS. 1A and 1B.

Hereinafter, the LED 130 will be described in detail.

The LED 130 includes an n-type electrode 131, an n-type layer 132, an active layer 133, a p-type layer 134, and a p-type electrode 135. A detailed layout structure of the LED 130 as a structure in which the n-type electrode 131 and the active layer 133 are located at the upper portion of the n-type layer 132 and the p-type layer 134 and the p-type electrode 135 are sequentially located at the upper portion of the active layer 133 is a structure of a lateral type LED. Hereinafter, it will be described that the structure of the LED 130 is the lateral type, but the structure of the LED 130 is not limited thereto and it is also possible that the structure of the LED 130 is a vertical or flip type. In addition, the LED 130 may be a micro LED (a chip size is 100 μm or less) or a mini LED (the chip size is hundreds of μm).

The p-type electrode 135 located on a top layer among components of the LED 130 is connected to the source electrode 124 of the thin-film transistor 120 to be applied with second power voltage Vdd according to data voltage. The second power voltage Vdd provides a positive load to the p-type electrode 135.

The p-type layer 134 located at the lower portion of the p-type electrode 135 as a semiconductor layer which receives holes from the p-type electrode 135, and generates current by movement of holes having a positive potential as carriers may be made of a p-GaN based material. The p-GaN based material may be GaN, AlGaN, InGaN, AlInGaN, etc., and as impurities used for doping the p-type semiconductor layer, Mg, Zn, Be, etc., may be used.

The active layer 133 is disposed at the lower portion of the p-type layer 134. The active layer 133 may be disposed on the n-type layer 132, and may have a multi quantum well (MQW) structure having a well layer and a barrier layer higher than the well layer by a band gap. For example, the active layer 133 may have the multi quantum well structure such as AlGaInP, GaInP, InGaN, and GaN.

The n-type layer 132 located at the lower portion of the active layer 133 as a semiconductor which is supplied with electrons from the n-type electrode 131 and generates current by movement of free electrons having a negative charge as the carriers may be made of an n-GaN based material. The n-GaN based material may be GaN, AlGaN, InGaN, AlInGaN, etc., and as impurities used for doping the n-type semiconductor layer, Si, Ge, Se, Te, C, etc., may be used. The n-type layer protrudes to the outside of the active layer. In other words, the active layer 133 and the p-type layer 134 may have a smaller area than the n-type layer 132 so as to expose an upper surface of the n-type layer 132.

The n-type electrode 131 is disposed at a portion protruded to the outside of the active layer 133 in the n-type layer 132. The n-type electrode 131 is connected to the common wire CL to be applied with the first power voltage Vss. The common wire CL is commonly connected to each LED 130 to apply predetermined voltage. The common wire CL provides the negative load to the n-type electrode 131.

As described above, the LED 130 may be used as the plurality of subpixels, and the LED 130 may be constituted by the green LED 130g and the blue LED 130b. In order for respective LEDs to emit different colors, the n-type layer, the active layer, and the p-type layer of the LED should be configured by different materials, and since different manufacturing processes are used, the manufacturing process is complicated.

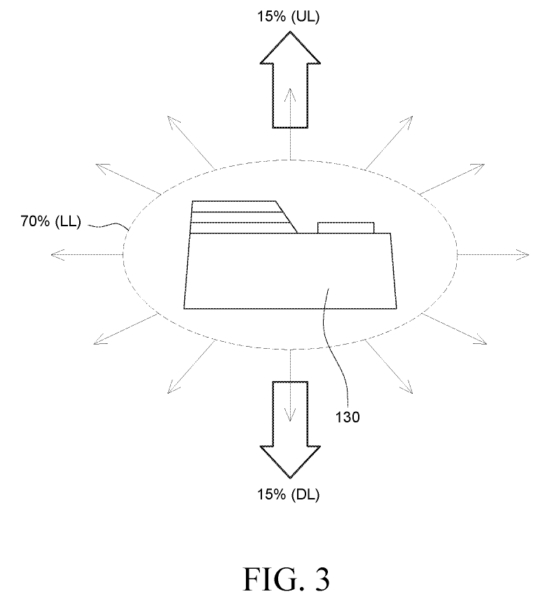

Meanwhile, referring to the LED light emitting ratio according to the direction of FIG. 3, the light generated from the LED 130 is omnidirectionally emitted toward the upper portion, the lower portion, and the lateral portion, and the light emitting ratio in each direction is emitted to each of the upper portion (UL) and the lower portion (DL) as 15%, and 70% is emitted to the lateral portion (LL) surrounding the LED. Only the light emitted to the upper portion among them is used for displaying, and the light emitted to the lateral portion and the lower portion is absorbed and destroyed by an internal component of the display device. That is, only the light of 15% radiated toward the upper portion in the light emitted from the LED is used for displaying the image.

Accordingly, in order to simplify the manufacturing process of the display device and reuse the light emitted to the lateral portion (LL) and destroyed in the light emitted from the LED, the color conversion layer according to the example embodiment of the present disclosure may be disposed.

Hereinafter, the color conversion layer will be described in detail with reference to FIG. 2.

Referring to FIG. 2, the color conversion layer may include a first color conversion layer 143 and a second color conversion layer 152. The first color conversion layer 143 surrounds the upper surface and the lateral surface of the blue LED 130b with a predetermined thickness, and serves to absorb light of a first color emitted from the blue LED 130b, convert the absorbed light of the first color into light of a second color, emit the converted light of the second color, and serves to absorb the light of the first color emitted from the blue LED 130b and block emitting the absorbed light to the outside. The second color conversion layer 152 is disposed at a position corresponding to the first color conversion layer 143, and serves to convert the light of the first color which is not converted by the first color conversion layer 143 or not absorbed and passes through the first color conversion layer 143 into the light of the second color, or absorb and destroy thereof.

Referring to FIG. 2, the first color conversion layer 143 may include a photo luminance (PL) material that absorbs the light of the first color, i.e., light of a first wavelength such as a nano fluorescent body, an organic fluorescent body, or a quantum dot, and emits the light of the second color, i.e., light of a second wavelength. The first color conversion layer 143 containing the photo luminance (PL) material may absorb blue light emitted from the blue LED 130b and radiated to the lateral portion (LL) and emit the blue light in omnidirectional portions including the upper portion. That is, the light radiated toward the lateral portion, which is destroyed inside the existing display device is absorbed and emitted to the upper portion to increase the luminous efficiency.

Further, when the color conversion layer is applied, in which the photo luminance (PL) material is distributed, such as the nano fluorescent body, the organic fluorescent body, or the quantum dot, light of different colors may be emitted by using the blue LED 130b. For example, the red light may be emitted or the green light may be emitted by using the blue LED 130b. That is, when the color conversion layer is used, in an existing configuration using different LEDs for each subpixel, light of different colors may be emitted by using the same LED in two or more subpixels to reduce an LED transfer process as described above.

The nano fluorescent body included in the color conversion layer is constituted by an activator performing a light emitting function and a host material accommodating the activator. The activator may adopt europium (Eu), manganese (Mn), cerium (Ce), terbium (Tb), erbium (Er), strontium (Sr), or scandium (Sc), the host material may adopt a potassium (K) compound, a strontium (Sr) compound, a calcium (Ca) compound, a silicon (Si) compound, and a gallium (Ga) compound. By combining the materials, the nano fluorescent body may adopt K₂SiF₆:Mn⁴⁺, Sr_{1-X}CaₓAlSiN₃:Eu²⁺, CaAlSiN₃:Eu²⁺, CaS:Eu²⁺, Sr₂Si₅N₈:Eu²⁺, (Sr,Ba)Si₂O₂N₂:Eu²⁺, α,β-SiAlON:Eu²⁺,GaS:Eu²⁺, etc. The nano fluorescent body is manufactured with a diameter size of 100 nm to 1.5 um.

Specifically, the nano fluorescent body as the photo luminance (PL) material has all of optically transmissive, reflective, and absorptive characteristics, most absorbed wavelengths are converted into a color of another wavelength and is emitted omnidirectionally, and other absorbed light has a feature that the light is extinguished as heat.

In a manufacturing method of the first color conversion layer 143 surrounding the blue LED 130b, a color conversion material layer may be formed by laminating a photosensitive dry film in which the material such as the nano fluorescent body, the organic fluorescent body, or the quantum dot is distributed on the display substrate and the color conversion material layer formed in a remaining area other than an area surrounding the lateral surface of the LED may be removed and formed through a photolithography process. Alternatively, the nano fluorescent body is distributed to an acryl based or epoxy based solution and applied to the display substrate, and cured to form the color conversion material layer and form the color conversion material layer by the photolithography process. Specifically, as the material of the color conversion material layer, photo acryl in which the nano fluorescent body is distributed may be used. Alternatively, a liquid color conversion material may be applied and cured only around the LED 130 by an inkjet printing scheme to form the first color conversion layer 143.

The second color conversion layer 152 formed in the color conversion substrate 150 may also be formed by the same method as the first color conversion layer 143, but a partition type second black matrix 156 is formed in the color conversion substrate 150, so the second color conversion layer 152 is formed by a method for filling a space between the second black matrices 156 by an inkjet printing scheme.

Meanwhile, the color conversion layer has characteristics in that a color conversion rate and a color absorption rate are shown differently according to the thickness of the color conversion layer or the concentration of the nano fluorescent body to derive and apply an optimal condition for the thickness and concentration of the color conversion layer. Here, the concentration means a ratio of the nano fluorescent body distributed in the liquid color conversion material for manufacturing the color conversions layer. The concentration is represented as wt% and the wt% means a weight of the nano fluorescent body distributed in a solution of 100 g.

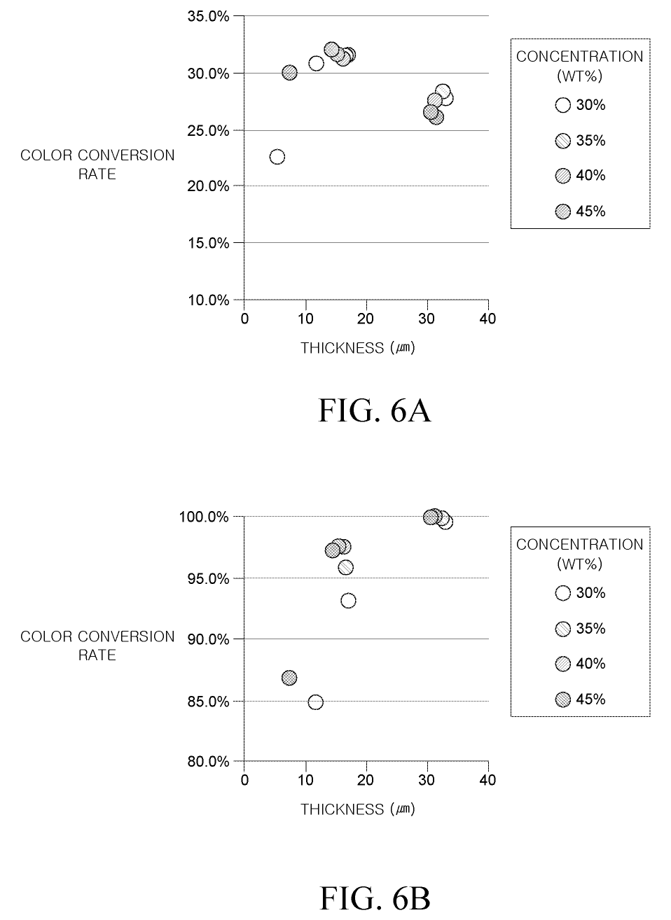

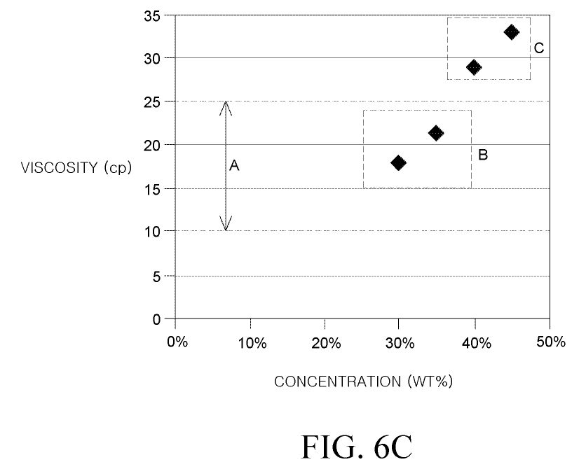

FIG. 6A is a diagram regarding a color conversion rate representing a ratio at which light of the blue LED 130b is converted into the red light in the color conversion layer according to the thickness of the color conversion layer and the concentration of the nano fluorescent body. An X axis of FIG. 6A indicates the thickness of the color conversion layer, and indicates a thickness (A + B) acquired by adding a first color conversion layer thickness A and a second color conversion layer 152 thickness B located at the upper portion of the LED in the first color conversion layer 143 of FIG. 2. A color conversion rate of a Y axis is a color conversion rate indicated when the nano fluorescent body concentration is changed to 30 wt%, 35 wt%, 40 wt%, and 45 wt%, and applied in each thickness while the color conversion layer thickness is changed to 1 to 40 μm.

FIGS. 6A and 6B illustrate a result of preponderantly testing in a range in which an optimal result is determined to be derived based on existing data for efficient result derivation, and a result value in an entire range is omitted.

In FIG. 6A, when the thickness is 15 μm, the color conversion rate shows a highest color conversion rate value of 30% or more, and it is shown that there is not a large difference in color conversion rate according to the change in concentration of the nano fluorescent body.

FIG. 6B is a diagram regarding a color absorption rate representing a ratio at which the light of the blue LED 130b is absorbed by the color conversion layer according to the same thickness and concentration condition as in FIG. 6A. When the thickness is 30 μm or more, the color absorption rate is shown as 100%, and there is no large difference in color conversion rate according to the concentration change in the thickness of 30 μm or more. When the thickness is 15 μm, the color absorption rate is shown as 93% or more, and when the concentration is 40 wt%, the color absorption rate is shown as 97% or more.

FIG. 6C is a diagram illustrating a viscosity changed according to the concentration change. The X axis of FIG. 6C indicates the concentration (wt%) of the nano fluorescent body, and the Y axis indicates a viscosity (cp) according to the concentration change of the liquid color conversion material. FIG. 6C shows a feature that as the concentration is the lower, the viscosity is the lower and as the concentration is the higher, the viscosity is the higher. When the liquid color conversion material is discharged from a nozzle of an inkjet or dispenser device, the viscosity of the liquid color conversion material should have a viscosity of a predetermined level or more in order to prevent the liquid color conversion material from flowing down without being formed in the nozzle. Further, the liquid color conversion material should have a viscosity of a predetermined level or less so as to control the liquid color conversion material in a desired form in terms of the manufacturing process.

A range represented by A of FIG. 6C as an allowed viscosity of the liquid color conversion material has a range of 10 25 cp. The liquid color conversion material having the viscosity of the allowed range as 30 to 35 wt% is a range of B of FIG. 6C. In this case, the viscosity has 17 to 22 cp. The concentration of the color conversion material included in a range of C of FIG. 6C is 40 wt% or more and the viscosity which exceeds 25 cp and the color conversion material has a viscosity at which it is difficult to use the color conversion material in the manufacturing process.

Therefore, when the results of FIGS. 6A, 6B, and 6C are summarized, in terms of the color conversion rate, the color absorption rate, and the manufacturing process, it is appropriate that the thickness of the color conversion material layer is 15 μm to 30 μm and it is appropriate that the concentration of the color conversion material layer is 30 wt% to 35 wt%.

The color conversion material is discharged onto the display substrate to form the color conversion material layer, and has the same property as the color conversion material layer. Since the liquid color conversion material layer is cured by using ultraviolet UV rays, differences between the liquid color conversion material layer and the cured color conversion material layer in the concentration and the thickness are slight. Even though the cured color conversion material layer 143m is patterned with the first color conversion layer 143 or the second color conversion layer 152, there is almost litter change in concentration and thickness.

Further, the concentrations of the first color conversion layer 143 and the second color conversion layer 152 may also be configured differently. For example, in the case of the first color conversion layer 143, by considering the manufacturing process, the concentration may be set to 30 wt% or less and in the case of the second color conversion layer 152, the concentration may be set to 45 wt% or less in order to increase the color absorption rate.

Hereinafter, an overall structure of the display device illustrated in FIGS. 2, 4, and 5 will be described in detail.

The display device according to an example embodiment of the present disclosure includes a display substrate 110 and an LED 130 disposed on the display substrate 110. The display substrate 110 as a substrate supporting components disposed at the upper portion of the display device 100 may be an insulating substrate. For example, the display substrate 110 may be made of a transparent material such as glass or plastic, and also made of a glass or plastic material having flexibility.

A pixel area may be defined on the display substrate 110. The pixel area may include the subpixel area, and the green LED 130g or the blue LED 130b used as the subpixel may be disposed in each subpixel area or only the blue LED 130b may be disposed. Further, the thin-film transistor 120 and various wires for driving each LED 130 may be formed in the subpixel area. The thin-film transistor 120 controls each LED 130, and when the thin-film transistor 120 is turned on, a driving signal input from the outside through the wire is applied to the LED 130 which emits light and implements the image.

The first planarization layer 111 is disposed at the upper portion of the thin-film transistor 120 so as to planarize the upper surface of the thin-film transistor 120. The first planarization layer 111 may be formed to planarize the upper portion in an area where the thin-film transistor 120 is disposed and an area other than a first contact hole. The first planarization layer 111 may be constituted by a single layer or multiple layers of photo acryl, transmissive epoxy, silicon oxide (SiOx), or silicon nitride (SiNx).

The first contact hole for exposing a part of the source electrode 124 of the thin-film transistor 120 and a part of the common wire CL is formed in the first planarization layer 111, and a plurality of connection portions is disposed in the first contact hole. The plurality of connection portions includes a first connection portion 126 and a second connection portion 127. One end of the first connection portion 126 is connected to the source electrode 124 of the thin-film transistor and the other end is connected to the p-type electrode 135 of the LED 130 through a first connection wire 141. One end of the second connection portion 127 is connected to the common wire CL and the other end is connected to the n-type electrode 131 of the LED through a second connection wire 142.

The LED 130 may be disposed on the first planarization layer 111 through the transfer process. The first color conversion layer 143 may be disposed to surround the upper portion and the lateral portion of the LED 130 around the LED 130 requiring color conversion. In addition, for electrical connection of the LED 130, a plurality of second contact holes for exposing the p-type electrode 135 and the n-type electrode 131 of the LED 130 is formed at the upper portion of the first color conversion layer 143.

The second planarization layer 145 may be disposed at the lateral portion of the first color conversion layer 143 and a peripheral portion of the LED 130 where the first color conversion layer 143 is not formed. The second planarization layer 145 may planarize upper surfaces of the LED 130 and the first color conversion layer 143 by filling spaces among all components including the LED 130 formed on the first planarization layer 111. The second planarization layer 111 may be constituted by the single layer or multiple layers of photo acryl, transmissive epoxy, silicon oxide (SiOx), or silicon nitride (SiNx) similarly to the first planarization layer 111.

In addition, a third contact hole is formed in an area where the first connection portion 126 and the second connection portion 127 are located in the second planarization layer 145 to expose the first connection portion 126 and the second connection portion 127.

The first connection wire 141 may be disposed to electrically connect the first connection portion 126 exposed through the third contact hole, and the p-type electrode 135 of the LED, and the second connection wire 142 may be disposed to electrically connect the second connection portion 127 exposed through the third contact hole, and the n-type electrode 131 of the LED 130. Specifically, one end of the first connection wire 141 may be in contact with the p-type electrode 135 of the LED 130, and the other end may be in contact with the first connection portion 126. One end of the second connection wire 142 may be in contact with the n-type electrode 131 of the LED 130, and the other end may be in contact with the second connection portion 127.

In the case of a structure in which the first connection portion 126 and the second connection portion 127 are not formed, the first connection wire 141 may be directly connected to the source electrode 124 of the thin-film transistor 120, and the second connection wire 142 may be directly connected to the common wire CL.

The first black matrix 144 is disposed on a part of each of the first connection wire 141, the second connection wire 142, the second planarization layer 145, and the first color conversion layer 143. The first black matrix 144 may be disposed on a boundary between the LEDs 130 which are the subpixels. The first black matrix 144 may shield light radiated toward another LED 130 among the light emitted from each of the LEDs 130 or reduce color mixture of the light. The first black matrix 144 may be formed by using a photoresist material mixed with a carbon black material and entirely applying the photoresist material onto the display substrate, and through the photolithography process. In addition, in the second black matrix 156 formed in the color conversion substrate 150, a photosensitive polyimide dry film (PID) or an acryl based dry film including the carbon black material may be formed through the lamination process and the photolithography process.

When the first black matrix 144 formed on the second planarization layer 145 is formed at the same height as an upper end height of the first color conversion layer 143, an entire surface may be planarized, so the third planarization layer to be described below may not be formed.

The third planarization layer 146 may be formed to be disposed on the first black matrix 144, the first color conversion layer 143, the first connection wire 141, and the second connection wire 142 to cover the entirety of the upper portion of the display substrate 110.

The third planarization layer 146 is a layer for protecting the LED 130 on the display substrate 110 and facilitating attachment to the color conversion substrate 150 to be described below. The third planarization layer 146 may be constituted by the single layer or multiple layers of photo acryl, transmissive epoxy, silicon oxide (SiOx), or silicon nitride (SiNx), similarly to the first planarization layer 111.

When the entire surface is planarized by the first black matrix 144, the third planarization layer 146 need not be disposed.

The color conversion substrate 150 is disposed on the third planarization layer 146. The color conversion substrate 150 is configured to include a transparent film 157, the second color conversion layer 152, the second black matrix 156, a transparent layer 153, and an adhesive layer 151. The adhesive layer 151 is disposed at the lower portion, and a plurality of second color conversion layers 152 is disposed on the adhesive layer to correspond to positions of the first color conversion layers 143. The transparent film 157 is disposed on the second color conversion layer 152.

The adhesive layer 151 may include optical clear resin (OCR), optically clear adhesive (OCA), or pressure sensitive adhesive (PSA) which has an excellent adhesive strength, and is capable of enhancing visibility.

The color conversion substrate 150 may be manufactured separately from the display substrate 110, and adhered to the third planarization layer 146 by an adhesive layer, and manufactured. It is also possible to directly form the color conversion substrate 150 on the third planarization layer 146 without the adhesive layer 151.

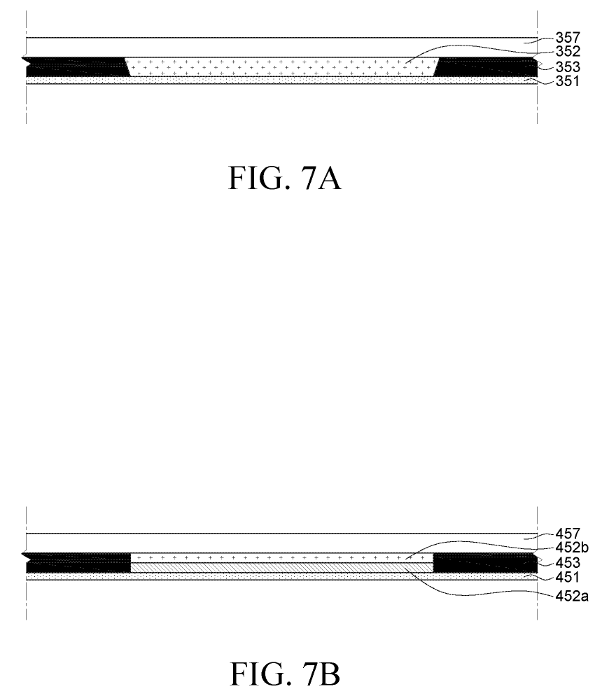

The second color conversion layer 152 may include the same nano fluorescent body, organic fluorescent body, or quantum dot as the first color conversion layer 143, and may be constituted by a color filter 352 including a pigment or a dye made of a carbon compound as illustrated in FIG. 7A. Since the color filter only serves to absorb light of an unnecessary color differently from the nano fluorescent body, the luminous efficiency may be lowered. Further, as illustrated in FIG. 7B, a color filter layer 452a made of the carbon compound and a nano fluorescent body layer 452b made of an inorganic material may also be laminated.

Referring to FIGS. 4 and 5, one or more second black matrices 156 and 256 may be disposed between the plurality of second conversion layers 152 and 252. In addition, one or more transparent layers 153 and 253 may be disposed between the plurality of second black matrices 156 and 256. In addition, the transparent films 157 and 257 are disposed on the second color conversion layers 152 and 252, the second black matrices 156 and 256, and the transparent layers 153 and 253.

FIG. 4 illustrates an example embodiment for an entire pixel area including the red subpixel area of FIG. 2.

Referring to FIG. 4, the green LED 130g is disposed in the green subpixel area on the first planarization layer 111, and the blue LED 130b is disposed in the blue subpixel area and the red subpixel area. The first color conversion layer 143 converting the blue light into the red light is disposed on a circumference of the blue LED 130b of the red subpixel area, and the second color conversion layer 152 of the color conversion substrate 150 is disposed to correspond to the first color conversion layer 143. The second color conversion layer 152 converts the blue light into the red light similarly to the first color conversion layer 143.

When the first color conversion layer 143 is not disposed around the green LED 130g disposed in the green subpixel area and the blue LED 130b disposed in the blue subpixel area, the second color conversion layer 151 is not disposed even in the color conversion substrate 150 and the transparent layer 153 is disposed to correspond to the green LED 130g and the blue LED 130g.

In addition, the second black matrix 156 of the color conversion substrate 150 is disposed between the second color conversion layer 152 and the transparent layer 153, and between the plurality of transparent layers 153.

FIG. 5 illustrates another example embodiment for the pixel area, and the blue LED 130b is disposed in the red subpixel area, the green subpixel area, and the blue subpixel area on the first planarization layer 211. A first red color conversion layer 243r converting the blue light into the red light is disposed on the circumference of the blue LED 230b of the red subpixel area, and a first green color conversion layer 243g converting the blue light into the green light is disposed on the circumference of the blue LED 230b of the green subpixel area. In addition, the first color conversion layers 243r and 243g are not disposed in the blue LED 230b disposed in the blue subpixel area, and the transparent layer 253 of the color conversion substrate 250 is disposed to correspond to the blue subpixel area. In respect to disposing of the second color conversion layers 252r and 252g of the color conversion substrate 250, the second red color conversion layer 252r is disposed to correspond to the red subpixel area where the blue LED 230b is located and the second green color conversion layer 252g is disposed to correspond to the green subpixel area where the blue LED 230b is located.

In addition, the second black matrix 156 of the color conversion substrate 150 is disposed between the second red color conversion layer 252r and the second green color conversion layer 252g and between the transparent layer 153 and the second color conversion layers 252r and 252g.

Meanwhile, referring to FIGS. 4 and 5, the transparent films 157 and 257 are disposed on the second color conversion layer, the second black matrix, and the transparent layer. The transparent films 157 and 257 may be made of a transparent glass or transparent plastic material, and may be manufactured by a film made of polyethylene terephthalate (PET), polycarbonate (PC), polyethylene naphthalate (PEN), polyimide, and polyacrylate.

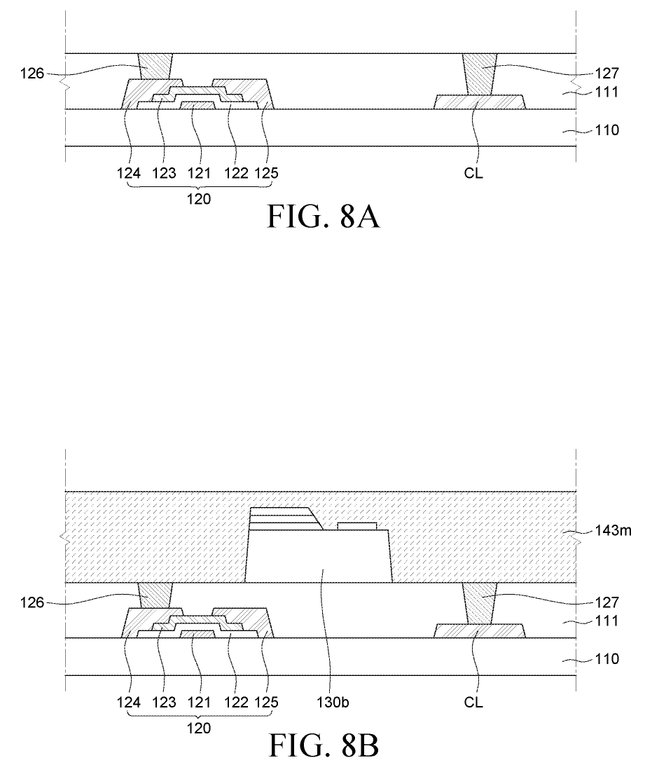

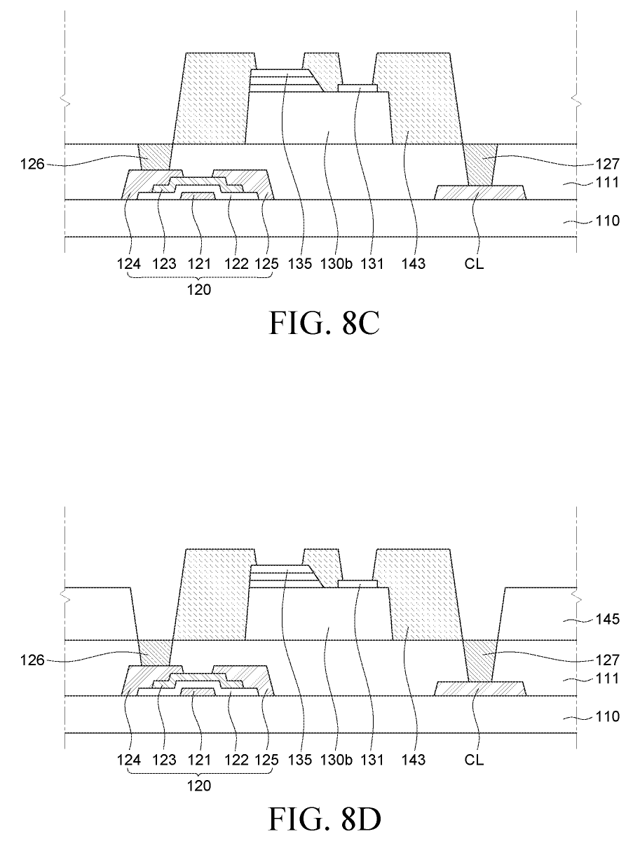

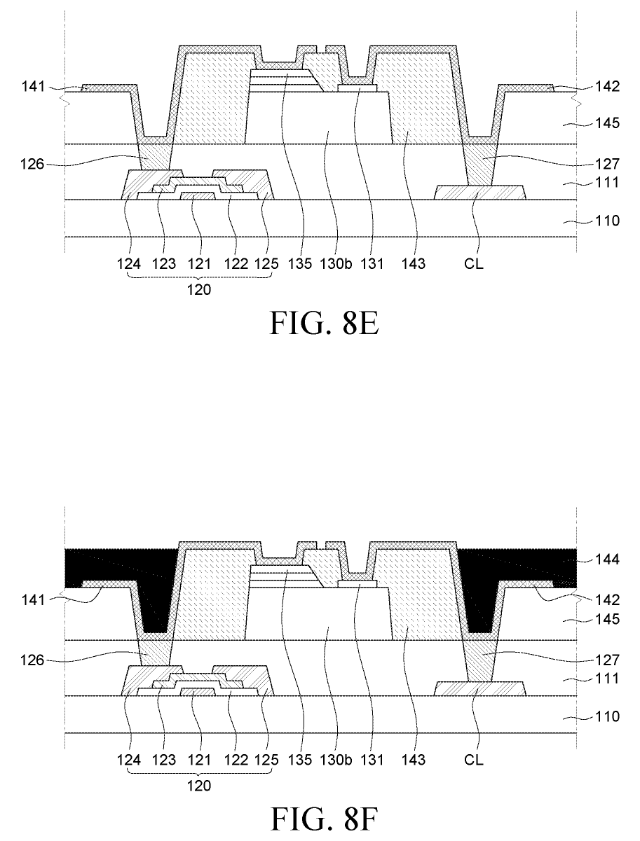

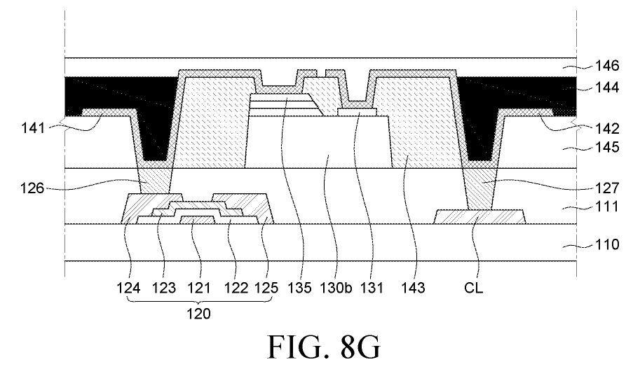

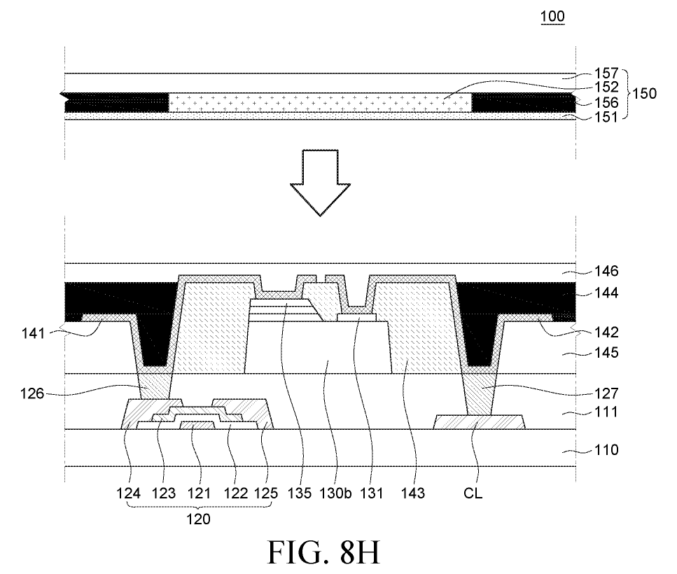

Hereinafter, a manufacturing method of the display device 100 according to an example embodiment of the present disclosure will be described in detail with reference to FIGS. 8A-8H.

FIGS. 8A-8H are diagrams regarding an example embodiment of converting the blue light emitted from the blue LED 130b into the red light. The display device of the example embodiment adopts the blue LED 130b and the green LED 130g, and is a structure in which the first color conversion layer 143 is formed in some blue LEDs 130b to convert and emit the blue light emitted from the blue LED 130b into the red light.

Referring to FIG. 8A, in order to drive the display device 100, a thin-film transistor TFT is formed on the display substrate 110, which is constituted by the gate electrode 121, the active layer 123, the source electrode 124, and the drain electrode 125. As the thin-film transistor, thin-film transistors 120 having various structures may be formed, such as a thin-film transistor of a bottom gate structure in which the gate electrode 121 is located below the active layer 123 or a thin-film transistor of a top gate structure in which the gate electrode 121 is located above the active layer 123. The common wire CL applying the second power voltage Vdd is made of the same metallic material as the source electrode 124 and the drain electrode 125 in the same order. The first planarization layer 111 for planarizing the surface is formed on the source electrode 124, the drain electrode 125, and the common wire CL.

After the first planarization layer 111 is formed, a plurality of first contact holes for exposing the source electrode 124 and the common wire CL is formed through the photolithography process. The plurality of first contact holes is filled with the conductive material to form the first connection portion 126 and the second connection portion 127. Specifically, as the first connection portion 126 and the second connection portion 127, a single material such as copper (Cu), aluminum (Al), silver (Ag), molybdenum (Mo), chromium (Cr), tantalum (Ta), or titanium (Ti) or a low-resistance opaque conductive material of an alloy in which two materials are combined may be used.

Next, as illustrated in FIG. 8B, the blue LED 130b is transferred onto the first insulating layer 111. In order to fix all LEDs 130 including the blue LED 130b onto the first insulating layer 111, the adhesive may be used at the lower portion of the LED 130. The LED 130 is fixed, and then an acryl based solution in which the nano fluorescent body is distributed is entirely applied, and cured to form the color conversion material layer 143m. The color conversion material layer 143m may be formed even by a method for entirely laminating an acryl based dry film in which the nano fluorescent body is distributed.

Next, as illustrated in FIG. 8C, a portion of the cured color conversion material layer 143m, which surrounds the lateral surface of the blue LED 130b is left and the remaining portion is removed through the photolithography process to form the first color conversion layer 143. In addition, the color conversion material layer 143m at the upper portions of the p-type electrode 135 and the n-type electrode 131 of the LED 130b is also removed to form a second contact hole, and connect the blue LED 130b to the first power voltage Vss and the second power voltage Vdd.

Next, as illustrated in FIG. 8D, after the second planarization layer 145 is formed at the entire upper portion of the first planarization layer 111, the second planarization layer 145 on the first connection portion 126 and the second connection portion 127 is removed to form a third contact hole for exposing the first connection portion 126 and the second connection portion 127. The second planarization layer 145 is formed with a smaller thickness than the first color conversion layer 143 to form the first black matrix 144 to be described below on the second planarization layer 145.

Next, as illustrated in FIG. 8E, the first connection wire 141 and the second connection wire 142 connecting the first connection portion 126 and the second connection portion 127 exposed by removing the second planarization layer 145 to the blue LED 130b are formed. Specifically, the first connection wire 141 may be formed to electrically connect the first connection portion 126 exposed through the third contact hole and the p-type electrode 135 of the blue LED 130b exposed through the second contact hole, and the second connection wire 142 may be formed to electrically connect the second connection portion 127 exposed through the third contact hole and the n-type electrode 131 of the blue LED 130b exposed through the second contact hole. A forming structure of the connection wire may be equally applied to the LEDs 130 including the blue LED 130b.

The first connection wire 141 and the second connection wire 142 may be formed through the photolithography process or a lift-off process. The lift-off process is a process in which when the photoresist PR is formed in an area other than a portion where the connection wire is formed, and connection wire metal is formed in an entire area, and then the photoresist is removed, the connection wire metal formed in the photoresist area is removed and the connection wire metal is left in an area where the photoresist is not formed and the connection wire is formed.

Next, as illustrated in FIG. 8F, the first black matrix 144 is formed on the second planarization layer 145 in which the blue LED 130b and the first color conversion layer 143 are not disposed. The first black matrix 144 may be formed by the process such as photolithography, etc., and is formed in the same height as the upper end height of the first color conversion layer 143 to planarize the entire surface. When the surface is planarized by the first black matrix 144, the first black matrix 144 may serve as the third planarization layer 146 to be described below, so the third planarization layer 146 is not required.

The first black matrix 144 is filled even in the third contact hole formed to expose the first connection portion 126 and the second connection portion 127 to serve to planarize the surface and serve to prevent the first connection wire 141 and the second connection wire 142 formed in the third contact hole from being viewed.

Next, as illustrated in FIG. 8G, the third planarization layer 146 may be formed on the surface where the first black matrix 144 and the first color conversion layer 143 are formed. The third planarization layer 146 may be constituted by photo acryl, transmissive epoxy, silicon oxide (SiOx), or silicon nitride (SiNx). The third planarization layer 146 is formed on the first black matrix 144, the first color conversion layer 143, and the LED 130 to planarize the surface in order to facilitate the attachment of the color conversion substrate 150 to be described below, and when the surface is planarized by the first black matrix 144, the third planarization layer 146 need not be formed.

Last, as illustrated in FIG. 8H, the color conversion substrate 150 is attached to the third planarization layer 146 to manufacture the display device 100. In the case of a structure in which the third planarization layer 146 is not formed, the color conversion substrate 150 is attached onto the LED 130, the first color conversion layer 143, and the first black matrix 144 to manufacture the display device.

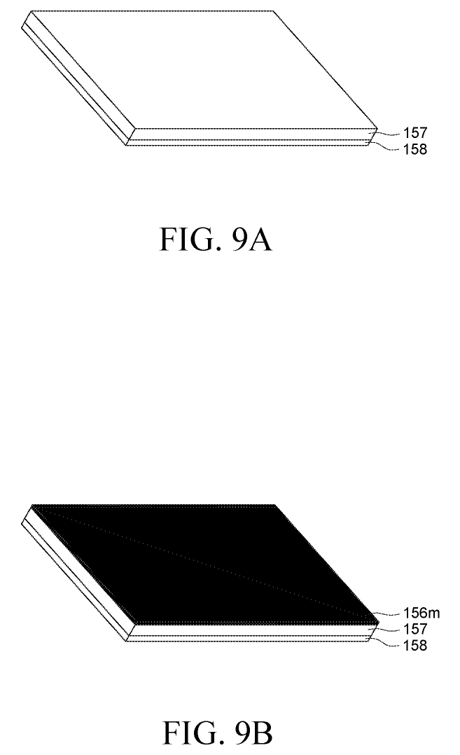

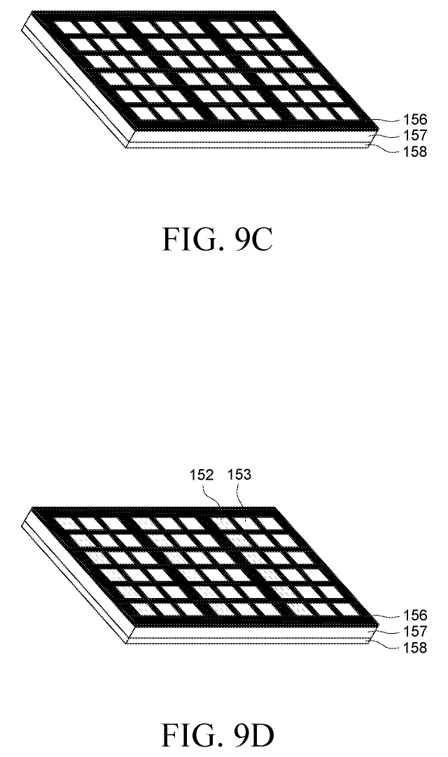

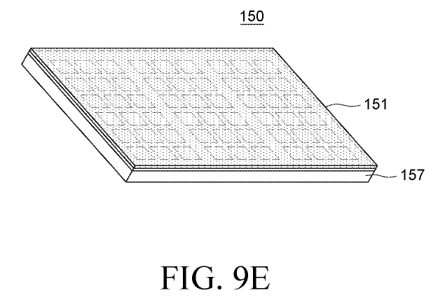

Further, the color conversion substrate 150 may be manufactured in the order illustrated in FIGS. 9A-9E.

Referring to FIG. 9A, in order to manufacture the color conversion substrate 150, the transparent film 157 made of the transparent glass or plastic material is attached to a carrier substrate 158 formed by glass or a wafer through lamination in a vacuum environment at an appropriate temperature. The carrier substrate 158 as a substrate temporarily used for manufacturing the color conversion substrate 150 is used for supporting the transparent film, and is separated from the color conversion substrate 150, and removed in a last step.

Referring to FIG. 9B, the black matrix film 156m made of a photosensitive material is attached onto the transparent film 157 in the vacuum environment at the appropriate temperature.

Referring to FIG. 9C, the black matrix film 156m made of the photosensitive material, which is attached onto the transparent film 157 is exposed and developed through a mask to form the second black matrix 156 having a partition structure.

Referring to FIG. 9D, a liquid color conversion material is filled into a space where the second color conversion layer 152 should be located in an empty space between the second black matrices 156 having the partition structure by an inkjet printing process, etc. Specifically, the liquid color conversion material is located in a subpixel area requiring color conversion in response to the first color conversion layer 143, and cured to form the second color conversion layer 152 and an optical curable solution in which a material such as TiO₂ is distributed is filled in a subpixel area not requiring the second color conversion layer 152 to form the transparent layer 153.

FIG. 9E is a diagram in which the carrier substrate 158 attached to the lower portion of the transparent film 157 is separated, and the adhesive layer 151 such as an optical clear adhesive (OCA) is applied onto the second black matrix 156, the second color conversion layer 152, and the transparent layer 153 at the upper portion of the transparent film 157 to manufacture a final color conversion substrate 150.

The color conversion substrate 150 manufactured through the process has flexibility, so the color conversion substrate 150 may be easily attached onto the display substrate with the LED 130.

In an example embodiment of the present disclosure, the LED 130 may adopt a micro LED or a mini LED. The micro LED and the mini LED may be distinguished according to a size and whether a sapphire substrate used as a growth substrate being removed, and specifically, the size of the LED is 100 μm or less, and an LED of a form in which the growth substrate is removed is categorized into the micro LED, and the size of the LED is hundreds of μm, and an LED of a form in which the growth substrate is not removed is categorized into the mini LED. In addition, a package LED which is commercialized, and used for a general illumination as a structure a size is 500 μm or more, and a fluorescent material is applied to an LED chip is a structure in which a lens may be disposed at the upper portion.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

1. A display device comprising:
a substrate including a plurality of subpixels;
a plurality of transistors disposed in each of the plurality of subpixels on the substrate;
an insulating layer covering the plurality of transistors;
a plurality of light emitting diodes (LEDs) disposed in each of the plurality of subpixels on the insulating layer;
first connection wires electrically connected to the plurality of LEDs;
a second planarization layer covering the connection wires;
a first planarization layer disposed between the insulating layer and the second planarization layer, and
wherein the first planarization layer includes a black material, and
wherein the first planarization layer disposed a boundary between the plurality of LEDs.

2. The display device of claim 1, wherein the first planarization layer is disposed at side portions of the plurality of LEDs.

3. The display device of claim 1, further comprising:
a first color conversion layer disposed between at least some of the plurality of LEDs and the first planarization layer.

4. The display device of claim 3, wherein the first color conversion layer overlaps the first planarization layer in a horizontal direction.

5. The display device of claim 3, wherein the first color conversion layer is disposed to surround an upper surface and a lateral surface of the at least some of the plurality of LEDs and configured to convert light of a first color emitted from the at least some of the plurality of LEDs into light of a second color.

6. The display device of claim 3, further comprising:
a second color conversion layer disposed over the plurality of LEDs.

7. The display device of claim 6, further comprising:
a color conversion substrate facing the substrate on the second planarization layer, and
wherein the color conversion substrate includes:
the second color conversion layer overlapping the first color conversion layer;
a black matrix overlapping the first planarization layer; and
a transparent layer overlapping remaining ones of the plurality of the LEDs.

8. The display device of claim 7, wherein the color conversion substrate further includes:
a transparent film at an upper portion of the second color conversion layer, and
an adhesive layer at a lower portion of the second color conversion layer.

9. The display device of claim 6, wherein the plurality of LEDs are blue LEDs emitting blue light, and
wherein the first color conversion layer and the second color conversion layer convert the blue light emitted from the plurality of LEDs into red light or green light.

10. The display device of claim 6, wherein at least one of the first color conversion layer and the second color conversion layer includes a nano fluorescent body comprising an inorganic material, and
the nano fluorescent body absorbs light of a specific wavelength emitted from the at least some of the plurality of LEDs and emits light of another wavelength.

11. The display device of claim 10, wherein the nano fluorescent body comprises an activator configured to perform a light emitting function and a host material accommodating the activator,
wherein the activator is at least one of europium (Eu), manganese (Mn), cerium (Ce), terbium (Tb), erbium (Er), strontium (Sr), and scandium (Sc),
wherein the host material is at least one of a potassium (K) compound, a strontium (Sr) compound, a calcium (Ca) compound, a silicon (Si) compound, and a gallium (Ga) compound, and
a size of the nano fluorescent body is in a range of 100 nm to 1.5 μm.

12. The display device of claim 10, wherein a sum of a thickness of the first color conversion layer located at an upper portion of a light emitting layer of the at least some of the plurality of LEDs and a thickness of the second color conversion layer is in a range of 15 μm to 30 μm.

13. The display device of claim 10, wherein the nano fluorescent body made of the inorganic material included in at least one of the first color conversion layer and the second color conversion layer is distributed in an acryl based or epoxy based photosensitive material, and
a concentration of the nano fluorescent body included in the first color conversion layer and the second color conversion layer is 30 wt% to 35 wt%.

14. The display device of claim 10, wherein the nano fluorescent body made of the inorganic material included in the first color conversion layer is distributed in an acryl based or epoxy based photosensitive material, and
a concentration of the nano fluorescent body of the first color conversion layer is 30 wt% or less.

15. The display device of claim 10, wherein the nano fluorescent body made of the inorganic material included in the second color conversion layer is distributed in an acryl based or epoxy based photosensitive material, and
a concentration of the nano fluorescent body of the second color conversion layer is 45 wt% or less.

16. The display device of claim 6, wherein at least one of the first color conversion layer and the second color conversion layer is a color filter including a pigment or a dye made of a carbon compound.

17. The display device of claim 6, wherein the second color conversion layer includes a color filter layer made of a carbon compound and a nano fluorescent body layer made of an inorganic material.

18. The display device of claim 1, wherein the first connection wires electrically connect the plurality of transistors and the plurality of LEDs through contact holes adjacent to the first planarization layer.

19. The display device of claim 18, wherein the first connection wires are in direct contact with the first planarization layer.

20. The display device of claim 1, further comprising:
second connection wires electrically connect the plurality of LEDs to a common wire configured to transfer a power voltage through contact holes adjacent to the first planarization layer.
